(19) United States
(12) Patent Application Publication
(10) Pub. No.: US 2015/0370120 A1
(43) Pub. Date: Dec. 24, 2015

(54) DISPLAY DEVICE WITH HEAT DISSIPATING CHASSIS

(71) Applicant: SAMSUNG DISPLAY CO., LTD., Yongin-City (KR)

(72) Inventors: Young Dae Song, Busan (KR); Sang Hwan Lee, Chungcheongnam-do (KR)

(21) Appl. No.: 14/567,199

(22) Filed: Dec. 11, 2014

(30) Foreign Application Priority Data
Jun. 24, 2014 (KR) 10-2014--0077208

(51) Int. Cl. G02F 1/1333; H05K 1/14; G02F 1/133; H05K 1/02

(52) U.S. Cl. CPC G02F 1/133382; H05K 1/028; H05K 1/142; G02F 1/13306; G02F 1/133308; G02F 1/133345; H05K 2201/10136; G02F 2001/133314

(57) ABSTRACT

A display device includes a display panel and a driving circuit substrate disposed on the display panel. At least one flexible printed circuit board is coupled to the display panel and the driving circuit substrate. A driving chip is disposed on a first surface of the flexible printed circuit board. A bottom chassis is configured to accommodate the display panel. A flange is coupled to an edge portion of a rear surface of the bottom chassis. The flange includes a first fixing unit, a side surface portion extended from an end portion of the first fixing unit and having a vertically bent shape, and a second fixing unit extended from an end portion of the side surface portion and having a shape bent toward the outside of the bottom chassis. A heat dissipating chassis is coupled to the second fixing unit.

### CROSS-REFERENCE TO RELATED APPLICATION

This application claims priority under 35 U.S.C. §119 to Korean Patent Application No. 10-2014-0077208, filed on Jun. 24, 2014, in the Korean Intellectual Property Office, the disclosure of which is incorporated by reference herein in its entirety.

### TECHNICAL FIELD

Exemplary embodiments of the present invention relate to a display device, and more particularly to a display device with a heat dissipating chassis.

### DISCUSSION OF RELATED ART

Examples of display devices include a liquid crystal display (LCD), an organic light emitting diode (OLED) display, a plasma display panel (PDP), and an electrophoretic display (EPD).

LCDs may include two substrates having electrodes disposed thereon and a liquid crystal layer disposed therebetween. A voltage may be applied to the electrodes, causing liquid crystal molecules of the liquid crystal layer to be rearranged, thereby controlling the amount of transmitted light.

To drive a liquid crystal panel of an LCD, printed circuit boards (PCB) may be disposed on at least one side surface of the liquid crystal panel using a chip on film (COF) or a tape carrier package (TCP). The COF or the TCP may include circuit lines so that electrical signals of a driving circuit substrate can be applied to the liquid crystal panel.

The PCB may be in contact with a rear surface of a bottom chassis. The COF or the TCP may be bent toward the side surface of the bottom chassis. In this configuration, a cover for accommodating the bottom chassis may be used to dissipate heat from the COF or the TCP.

To reduce thickness of a display device, the PCB may be disposed on a side surface of the bottom chassis. In this configuration, flanges may be formed protruding outwards along the side surface of the bottom chassis having a predetermined gap and a driving circuit substrate may be mounted on the flanges.

Display device might not include a separate structure for dissipating heat generated by the COF or the TCP.

### SUMMARY

Exemplary embodiments of the present invention are directed to a display device including a heat dissipating chassis configured to dissipate heat generated from a chip on film (COF) or a tape carrier package (TCP).

According to an exemplary embodiment of the present invention, a display device includes a display panel and a driving circuit substrate disposed on the display panel. At least one flexible printed circuit board is coupled to the display panel and the driving circuit substrate. A driving chip is disposed on a first surface of the flexible printed circuit board. A bottom chassis is configured to accommodate the display panel. A flange is coupled to an edge portion of a rear surface of the bottom chassis. The flange comprises a first fixing unit, a side surface portion extended from an end portion of the first fixing unit and having a vertically bent shape, and a second fixing unit extended from an end portion of the side surface portion and having a shape bent toward the outside of the bottom chassis. A heat dissipating chassis is coupled to the second fixing unit.

The second fixing unit may have a smaller width than a width between two flexible printed circuit boards that are disposed adjacent to each other.

The flange may include a wing unit protruding toward at least one side surface of the second fixing unit.

The driving circuit substrate may be disposed on a rear surface of the second fixing unit and the wing unit.

An insulating member may be disposed between the second fixing unit and the driving circuit substrate.

The wing unit may be in contact with a surface of the flexible printed circuit board.

The wing unit may be in contact with the driving chip.

The second fixing unit and the heat dissipating chassis may be spaced apart from and coupled to each other.

A separation distance between the second fixing unit and the heat dissipating chassis may be substantially the same as a thickness of the driving chip.

A separation distance between the wing unit and the heat dissipating chassis may be substantially the same as the thickness of the driving chip.

The flange may be disposed between two flexible printed circuit boards that are disposed adjacent to each other.

Another flange may be disposed between the two other flexible printed circuit boards that are disposed adjacent to each other.

The heat dissipating chassis may be in contact with a second surface of the flexible printed circuit board.

The heat dissipating member may be disposed between the heat dissipating chassis and the second surface of the flexible printed circuit board.

The first fixing unit may have a first coupling hole configured to be coupled to the bottom chassis.

The second fixing unit may have a second coupling hole configured to be coupled to the heat dissipating chassis.

The flange may include a same material as the bottom chassis.

The bottom chassis may have a groove configured to guide the first fixing unit.

The first fixing unit may be configured to be coupled to the bottom chassis with a screw.

The second fixing unit may be configured to be coupled to the heat dissipating chassis with a screw.

### BRIEF DESCRIPTION OF THE DRAWINGS

A more complete appreciation of the present invention will become more apparent by describing in detail exemplary embodiments thereof with reference to the accompanying drawings, wherein:

FIG. 1 is an exploded perspective view illustrating a display device according to an exemplary embodiment of the present invention;

FIGS. 2A to 2C are perspective views showing flanges according to exemplary embodiments of the present invention;

FIG. 3 is a plan view showing a display device according to an exemplary embodiment of the present invention;

FIG. 4 is a plan view of the display device of FIG. 3 without showing a heat dissipating chassis;

FIG. 5 is a cross-sectional view of part “A” of FIG. 4;

FIG. 6 is a cross-sectional view taken along line I-I′ of FIG. 5; and

FIG. 7 is a cross-sectional view taken along line II-II′ of FIG. 5.

### DETAILED DESCRIPTION

Hereinafter, exemplary embodiments of the present invention will be described in more detail with reference to the accompanying drawings. The present invention may, however, be embodied in many different forms and should not be construed as being limited to the embodiments disclosed herein.

Throughout the specification, when an element is referred to as being “connected” to another element, the element may be “directly connected” to the other element, or “electrically connected” to the other element with one or more intervening elements interposed therebetween.

Like reference numerals may refer to like elements throughout the specification and drawings.

Hereinafter, a liquid crystal display (LCD) may be included in a display device according to an exemplary embodiment of the present invention. However, exemplary embodiments of the present invention can be applied to an organic light emitting diode (OLED) display or a plasma display panel (PDP).

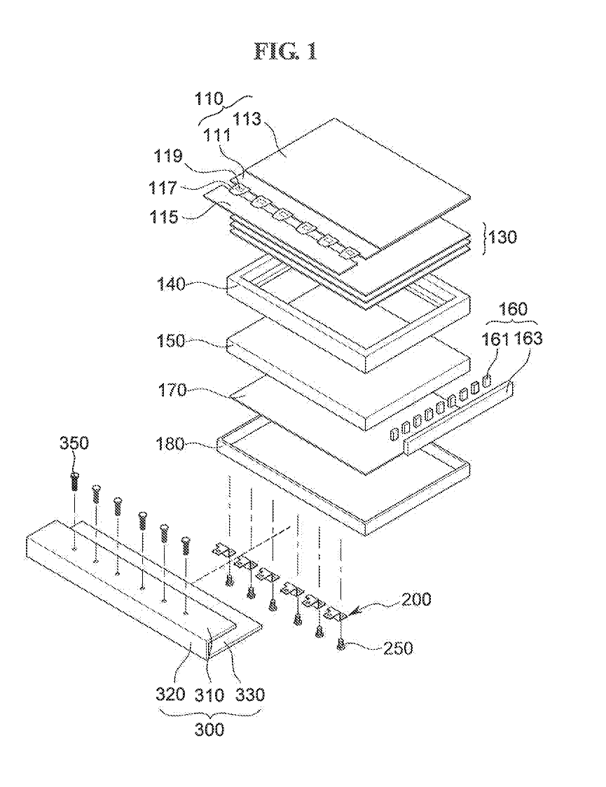

FIG. 1 is an exploded perspective view illustrating a display device according to an exemplary embodiment of the present invention.

With reference to FIG. 1, a display device according to an exemplary embodiment of the present invention may include a display panel 110, an optical sheet 130, a mold frame 140, a light guide plate 150, a light source unit 160, a reflective sheet 170, a bottom chassis 180, a flange 200, and a heat dissipating chassis 300.

A backlight unit may include the optical sheet 130, the mold frame 140, the light guide plate 150, the light source unit 160, the reflective sheet 170, and the bottom chassis 180.

The display device according to an exemplary embodiment of the present invention may be a slim-type display device that may fix a driving circuit substrate and the heat dissipating chassis 300 by using a plurality of flanges 200 coupled to the bottom chassis 180. Configurations of the flange 200 and the heat dissipating chassis 300 will be described below in more detail.

The display panel 110 may be disposed in a panel shape having a quadrilateral cross-section configured to display an image using light. The display panel 110 may include an LCD or an electrophoretic display. As mentioned above, in the current embodiment, the display panel 110 is an LCD.

The display panel 110 may include a first substrate 111, a second substrate 113 facing the first substrate 111, and a liquid crystal layer (not illustrated) disposed between the first substrate 111 and the second substrate 113.

The first substrate 111 may include a plurality of pixel electrodes arranged in a matrix, a thin film transistor configured to apply a driving voltage to the respective pixel electrodes, and signal lines configured to drive the pixel electrodes and the thin film transistor.

The second substrate 113 may be disposed to face the first substrate 111 and may include a common electrode including a transparent conductive material and a color filter. The color filter may be a red, green, or blue color filter.

The liquid crystal layer (not illustrated) may be disposed between the first substrate 111 and the second substrate 113 and may be rearranged in accordance with an electric field formed between the pixel electrode and the common electrode. The rearranged liquid crystal layer may adjust transmittance of light emitted from the backlight unit and the adjusted light may pass through the color filter, such that an image can be displayed.

Polarizing plates (not illustrated) may be respectively disposed on a rear surface of the first substrate 111 and a top surface of the second substrate 113. The polarizing plates may have an area corresponding to the display panel. The polarizing plates may only allow light having a predetermined polarization direction among light emitted from the backlight unit to pass through or may only allow light having a predetermined polarization direction among light incident from the outside to pass through and may absorb or block other light.

A driving circuit substrate 115 may be disposed on at least one side of the display panel 110. The driving circuit substrate 115 may apply driving signals to the signal lines disposed on the first substrate 111. The driving circuit substrate 115 may include a gate driving circuit substrate configured to apply scan signals and a data driving circuit substrate configured to apply data signals. In FIG. 1, the driving circuit substrate 115 may be disposed on only one side of the display panel 110; however, exemplary embodiments of the present invention are not limited thereto.

The display panel 110 and the driving circuit substrate 115 may be electrically connected to each other by at least a flexible printed circuit board 117. A first end portion of the flexible printed circuit board 117 may overlap a first part of the first substrate 111 and may be electrically connected to the first substrate 111. A second end portion of the flexible printed circuit board 117 may overlap a second part of the driving circuit substrate 115 and may be electrically connected to the driving circuit substrate 115. The flexible printed circuit board 117 may include, for example, the COF or the TCP. Hereinafter, in the current embodiment, the COF used as the flexible printed circuit board 117 may be described in more detail. In FIG. 1, six flexible printed circuit boards 117 are illustrated. However, exemplary embodiments of the present invention are not limited thereto, and thus the number of the flexible printed circuit boards 117 may be adjusted, as desired. For example, the number of flexible printed circuit boards 117 may be adjusted depending on the size and the driving methods of the display panel 110.

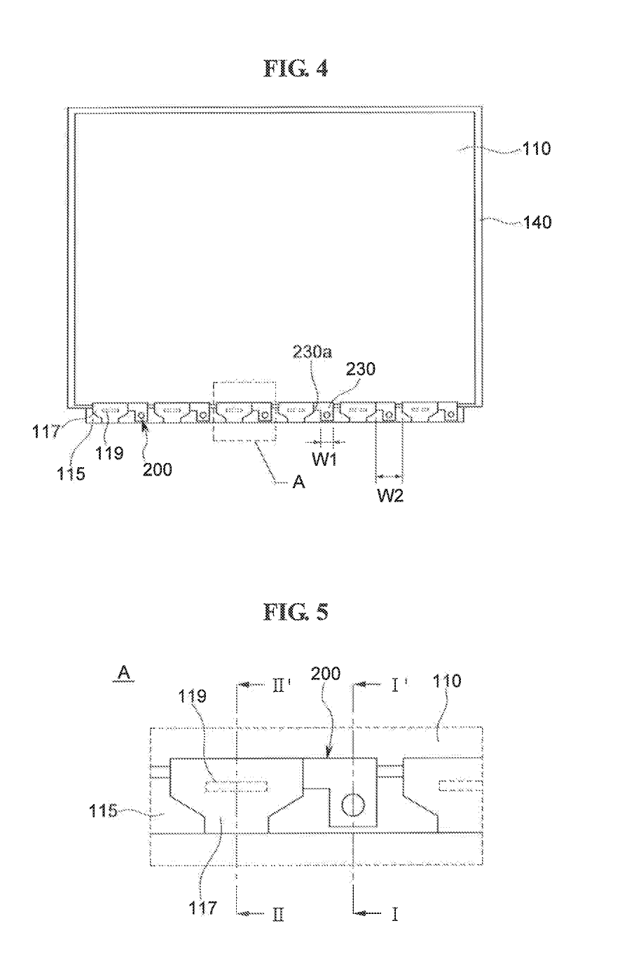

A driving chip 119 (see e.g., FIG. 4) may be mounted on the flexible printed circuit board 117. The driving chip 119 may generate driving signals for driving the display panel 110. The driving chip 119 may include a timing controller and a data driving circuit in a single chip. The driving chip 119 may include a driver integrated circuit (IC) or a source integrated circuit (IC).

The optical sheet 130 may be disposed on the light guide plate 150 and may be configured to diffuse and/or collect light transmitted from the light guide plate 150. The optical sheet 130 may include a diffusion sheet, a prism sheet, and/or a protective sheet. In FIG. 1, three optical sheets 130 are illustrated; however, two, four, or more optical sheets may be used.

The diffusion sheet may be configured to disperse light incident from the light guide plate 150 and may prevent the light from being partly concentrated.

The prism sheet may include prisms, which may have a triangular cross-section and may be aligned in a predetermined arrangement, on a surface thereof. The prism sheet may be disposed on the diffusion sheet and may collect light diffused from the diffusion sheet in a direction perpendicular to the display panel 110.

The protective sheet may be disposed on the prism sheet. The protective sheet may protect a surface of the prism sheet, may diffuse light, and may achieve a uniform light distribution.

The mold frame 140 may have a quadrilateral-loop shape and may accommodate and support the display panel 110, the optical sheet 130, and the light guide plate 150 inside the quadrilateral-loop shape. The mold frame 140 may be a single unit as illustrated in FIG. 1. However, the mold frame 140 may include a plurality of units.

The light guide plate 150 may uniformly direct light provided from the light source unit 160 to the display panel 110. The light guide plate 150 may be disposed adjacent to the light source unit 160 and may be accommodated in the bottom chassis 180. The light guide plate 150 may include a quadrilateral plate. However, exemplary embodiments of the present invention are not limited thereto, and thus in a case where a light emitting diode (LED) chip is used as a light source, the light guide plate 150 may have various shapes including predetermined grooves, protrusions, or the like depending on the position of the light source.

The light guide plate 150 may be referred to as a plate, but the light guide plate 150 may be in a shape of a sheet or a film forming a slim display device. In other words, the light guide plate 150 may include the film for guiding light.

The light guide plate 150 may include a light-transmissive material such as, for example, acrylic resins, such as polymethylmethacrylate (PMMA), or polycarbonate (PC).

The reflective sheet 170 may be disposed between the light guide plate 150 and the bottom chassis 180. The reflective sheet 170 may reflect light emitted downwards from the light guide plate 150 to the display panel 110, and may increase light transfer efficiency. The reflective sheet 170 may include, for example, polyethylene terephthalate (PET), and may reflect light. A surface of the reflective sheet 170 may be coated with a diffusion layer including, for example, titanium dioxide. The reflective sheet 170 may include a material containing a metal, such as silver (Ag).

The light source unit 160 may include a light source 161 and a circuit substrate 163 on which the light source 161 may be disposed. The light source 161 may be disposed at an edge portion or on a light incident surface of the light guide plate 150. In other words, the light source 161 may emit light toward the edge portion or the light incident surface of the light guide plate 150. The light source 161 may include at least one LED chip (not illustrated) and a package (not illustrated) for accommodating the LED chip. For example, the LED chip (not illustrated) may be a gallium nitride (GaN)-based LED chip that emits blue light.

The circuit substrate 163 may include a printed circuit board (PCB) or a metal PCB.

The light source unit 160 may be disposed on one side surface, both side surfaces, or all four side surfaces of the light guide plate 150, depending, for example, on the size and the luminance uniformity of the display panel 110. In other words, the light source unit 160 may be disposed on at least one edge portion of the light guide plate 150.

A wavelength converting unit (not illustrated) may be disposed between the light guide plate 150 and the light source unit 160. The wavelength converting unit (not illustrated) may include a substance that can change a wavelength of light. For example, the wavelength converting unit may change a wavelength of blue light emitted from a blue LED light source, so that the blue light may be converted to white light.

A heat dissipating member (not illustrated) may be disposed between the light source unit 160 and the bottom chassis 180. The heat dissipating member may release heat generated from the light source unit 160 to the outside. When the light source unit 160 is disposed on one side surface of the bottom chassis 180 in a bar or line shape, a metal frame having a bar or line shape may be disposed as the heat dissipating member. The heat dissipating member may have various shapes depending on the shape of the light source unit 160.

The bottom chassis 180 may include a rigid metal material such as stainless steel or a heat dissipating material such as aluminum or aluminum alloys. The bottom chassis 180 may be configured to maintain a framework of the display device and protect a variety of components accommodated therein.

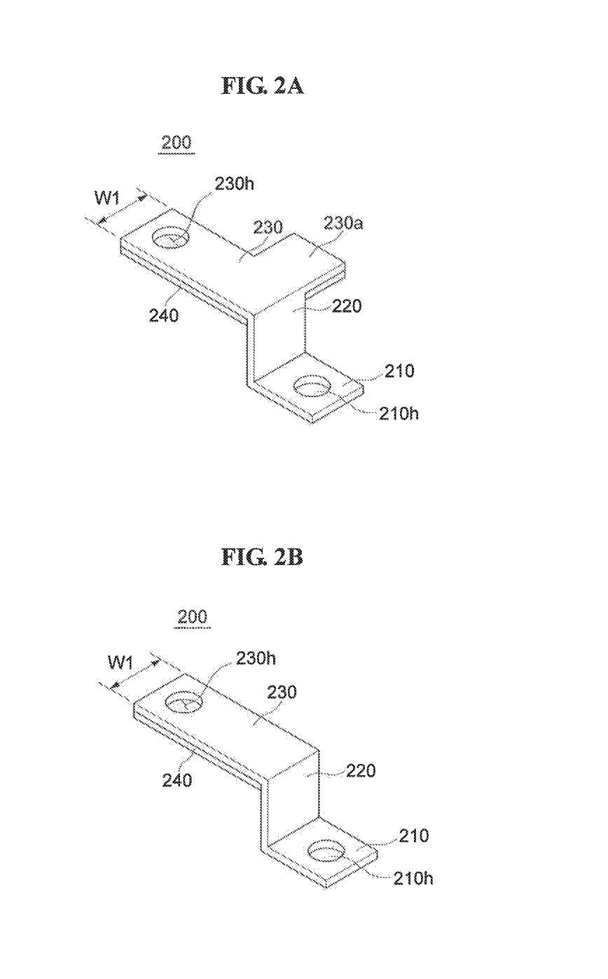

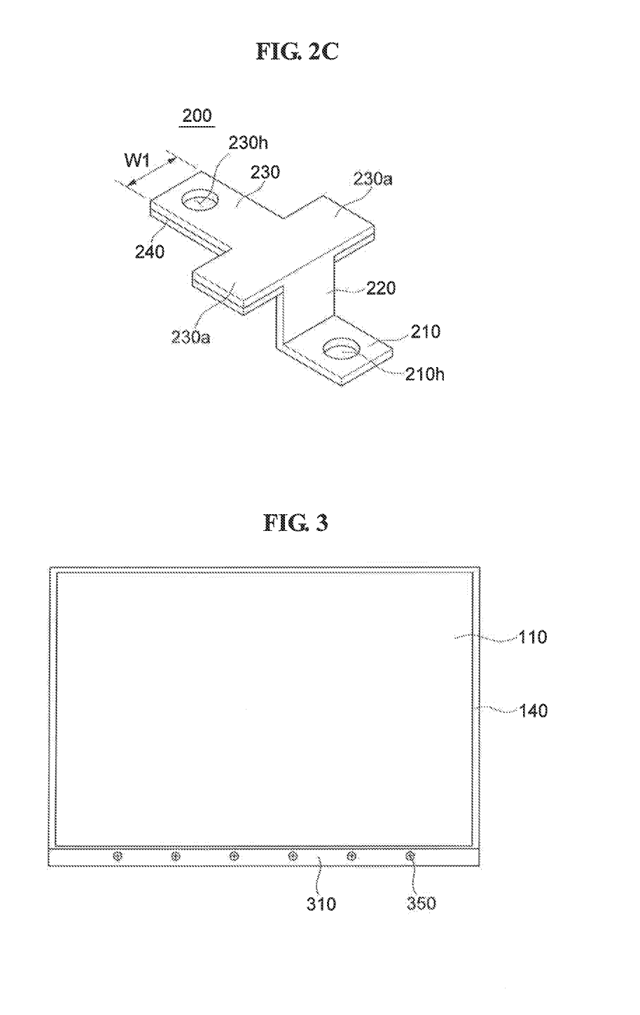

FIGS. 2A to 2C are perspective views showing flanges according to exemplary embodiments of the present invention.

Referring to FIGS. 1 and 2A, the flange 200 according to an exemplary embodiment of the present invention may include a relatively thin metal plate. The flange 200 may include a first fixing unit 210 fixed at an edge portion of a rear surface of the bottom chassis 180, a side surface portion 220 extended from an end portion of the first fixing unit 210 and having a vertically bent shape, and a second fixing unit 230 extended from an end portion of the side surface portion 220 and having a shape horizontally bent toward the outside of the bottom chassis 180.

The first fixing unit 210 according to an exemplary embodiment of the present invention may include a first coupling hole 210h, and the first fixing unit 210 may be configured to be coupled to the bottom chassis 180 using the first coupling hole 210h. The second fixing unit 230 may include a second coupling hole 230h, and the second fixing unit 230 may be configured to be coupled to the heat dissipating chassis 300 using the second coupling hole 230h. For example, the first fixing unit 210 and the bottom chassis 180 may be fixed using a screw 250 and the second fixing unit 230 and the heat dissipating chassis 300 may be fixed using a screw 350. The first fixing unit 210 and the second fixing unit 230 may be fixed by a variety of coupling methods, such as hook coupling.

The second fixing unit 230 of the flange 200 may be disposed in a space between two flexible printed circuit boards 117 disposed adjacent to each other, and the second fixing unit 230 of the flange 200 may have a smaller width W1 compared to a gap between the two flexible printed circuit boards 117 disposed adjacent to each other.

The second fixing unit 230 of the flange 200 may be disposed in a space between the two flexible printed circuit boards 117 disposed adjacent to each other, and the first fixing unit 210 may be fixed to the edge portion of the rear surface of the bottom chassis 180, and the heat dissipating chassis 300 may be fixed to the second fixing unit 230. A more detailed description of the flange 200 will be provided below.

Referring to FIG. 2A, the flange 200 may include a wing unit 230a protruding toward at least one side surface of the second fixing unit 230. The flange 200, according to an exemplary embodiment of the present invention, need not include a wing unit (see e.g., FIG. 2B) or may include a wing unit 230a protruding toward both side surfaces of the second fixing unit 230 (see e.g., FIG. 2C).

The wing unit 230a may be configured to be in contact with the driving chip 119 described below in more detail and may dissipate heat generated from the driving chip 119.

An insulating member 240 may be disposed on a rear surface of the second fixing unit 230 and the wing unit 230a protruding toward at least one side surface of the second fixing unit 230. The insulating member 240 may be bonded and fixed to the second fixing unit 230 and the wing unit 230a by a bonding member (not illustrated).

The insulating member 240 may electrically separate the driving circuit substrate 115 disposed on the rear surface of the second fixing unit 230 and the wing unit 230a from the flange 200.

The flange 200 may include a same material as the bottom chassis 180. The flange 200 may include a rigid metal material such as stainless steel or a heat dissipating material such as aluminum or aluminum alloys.

Referring to FIG. 1, the heat dissipating chassis 300 may include a relatively thin metal plate. The heat dissipating chassis 300 may include a first horizontal portion 310 fixed to the second fixing unit 230 of the flange 200, a vertical portion 320 extended from an end portion of the first horizontal portion 310 and having a vertically bent shape, and a second horizontal portion 330 extended from an end portion of the vertical portion 320 and having a horizontally bent shape.

The heat dissipating chassis 300 may be in contact with the flexible printed circuit board 117 on which the driving chip 119 described in more detail below is disposed and may dissipate heat generated from the driving chip 119.

FIG. 3 is a plan view showing a display device according to an exemplary embodiment of the present invention and FIG. 4 is a plan view of the display device of FIG. 3 without showing a heat dissipating chassis.

Referring to FIGS. 3 and 4, at least one flange 200 may be disposed on the side of the display panel 110 on which the driving circuit substrate 115 is disposed. In FIG. 4, six flanges 200 are illustrated; however, exemplary embodiments of the present invention are not limited thereto, and thus the number of flanges may be adjusted depending, for example, on the number of the flexible printed circuit boards 117.

The flange 200 may be disposed between the flexible printed circuit boards 117. The flanges 200 may be respectively disposed between two flexible printed circuit boards 117 disposed adjacent to each other. The position of the flanges 200 may vary depending on the shape of the flange 200.

For example, when the wing unit 230a is disposed on only one side of the flange 200, the flange 200 may be in contact with one of the flexible printed circuit boards 117 adjacent thereto. When the wing unit 230a is disposed on both sides of the flange 200, one flange 200 may be disposed to be in contact with every two adjacent flexible printed circuit boards 117.

A width W1 of the second fixing unit 230 of the flange 200 may be smaller than a gap W2 between the flexible printed circuit boards 117 disposed adjacent to each other. The second fixing unit 230 of the flange 200 may be disposed in a space between the two flexible printed circuit boards 117 disposed adjacent to each other, and the wing unit 230a of the flange 200 may be disposed in a space between the two flexible printed circuit boards 117 and the driving circuit substrate 115. The wing unit 230a of the flange 200 may be disposed in a space between the driving chip 119 of the flexible printed circuit board 117 and the driving circuit substrate 115.

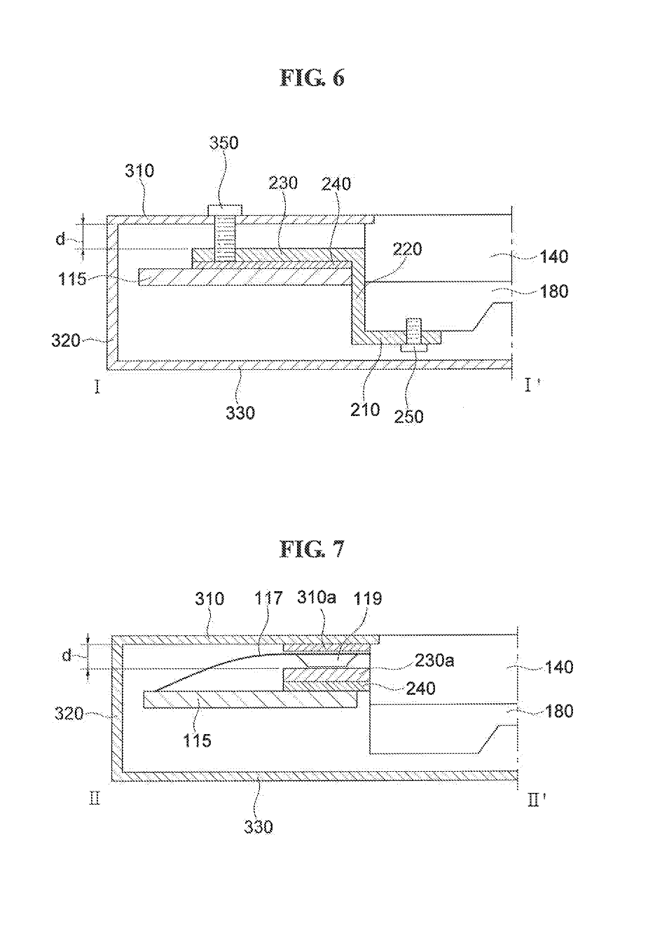

FIG. 5 is a cross-sectional view of part “A” of FIG. 4, FIG. 6 is a cross-sectional view taken along line I-I′ of FIG. 5, and FIG. 7 is a cross-sectional view taken along line II-II′ of FIG. 5.

Referring to FIGS. 5 to 7, the second fixing unit 230 of the flange 200 may be disposed in a space between the flexible printed circuit boards 117, and the first fixing unit 210 of the flange 200 may be disposed on the edge portion of the rear surface of the bottom chassis 180 by the screw 250. The first horizontal portion 310 of the heat dissipating chassis 300 may be coupled to the second fixing unit 230 of the flange 200 by the screw 350. For example, the first horizontal portion 310 and the second fixing unit 230 may be spaced apart by a predetermined distance when coupled together. A separation distance between the first horizontal portion 310 and the second fixing unit 230 may be substantially the same as a thickness of the driving chip 119. The separation distance d between the first horizontal portion 310 and the wing unit 230a may be substantially the same as the thickness of the driving chip 119.

A groove (not illustrated) may be disposed in the edge portion of the rear surface of the bottom chassis 180 on which the first fixing unit 210 is disposed. The groove may be configured to guide the first fixing unit 210 into position to be coupled to the bottom chassis 180.

The driving circuit substrate 115 may be disposed on a rear surface of the insulating member 240 disposed on the rear surface of the second fixing unit 230 and the wing unit 230a. The insulating member 240 and the driving circuit substrate 115 may be coupled to each other by a bonding member (not illustrated).

Referring to FIG. 7, the first horizontal portion 310 of the heat dissipating chassis 300 may be in contact with another surface of the flexible printed circuit board 117. For example, a heat dissipating member 310a may be disposed between the another surface of the flexible printed circuit board 117 and the first horizontal portion 310. The heat dissipating member 310a may be disposed between the another surface of the flexible printed circuit board 117, which may be an area on which the driving chip 119 is disposed, and the first horizontal portion 310.

The heat dissipating member 310a may include a rigid metal material such as stainless steel, a heat dissipating material such as aluminum or aluminum alloys, or elastic deformable silicon rubber. When the heat dissipating member 310a includes an elastic material, adhesion between the driving chip 119, the heat dissipating chassis 300, and the flange 200 may be increased, and the heat dissipation of the driving chip 119 may be increased.

The wing unit 230a of the flange 200 may be in contact with one surface of the flexible printed circuit board 117. The wing unit 230a may be in contact with the driving chip 119 that may be disposed on one surface of the flexible printed circuit board 117.

One surface of the driving chip 119 disposed on the flexible printed circuit board 117 and the flange 200 may be in contact with each other, another surface of the driving chip 119 and the heat dissipating chassis 300 may be in contact with each other, and heat generated by the driving chip 119 may be dissipated.

According to embodiments of the present invention, a display device fixes a driving circuit substrate and a heat dissipating chassis by using a detachable flange, thereby achieving slimness and improving a heat dissipating function.

While the present invention has been shown and described with reference to the exemplary embodiments thereof, it will be apparent to those of ordinary skill in the art that various changes in form and detail may be made thereto without departing from the spirit and scope of the invention as defined by the claims.

What is claimed is:

1. A display device, comprising:
a display panel;
a driving circuit substrate disposed on the display panel;
at least one flexible printed circuit board coupled to the display panel and the driving circuit substrate, wherein a driving chip is disposed on a first surface of the flexible printed circuit board;
a bottom chassis configured to accommodate the display panel;
a flange coupled to an edge portion of a rear surface of the bottom chassis, wherein the flange comprises a first fixing unit, a side surface portion extended from an end portion of the first fixing unit and having a vertically bent shape, and a second fixing unit extended from an end portion of the side surface portion and having a shape bent toward the outside of the bottom chassis; and
a heat dissipating chassis coupled to the second fixing unit.

2. The display device of claim 1, wherein the second fixing unit has a smaller width than a width between two flexible printed circuit boards that are disposed adjacent to each other.

3. The display device of claim 1, wherein the flange further comprises a wing unit protruding toward at least one side surface of the second fixing unit.

4. The display device of claim 3, wherein the driving circuit substrate is disposed on a rear surface of the second fixing unit and the wing unit.

5. The display device of claim 4, wherein an insulating member is disposed between the second fixing unit and the driving circuit substrate.

6. The display device of claim 3, wherein the wing unit is in contact with the driving chip.

7. The display device of claim 1, wherein the second fixing unit and the heat dissipating chassis are spaced apart from and coupled to each other.

8. The display device of claim 7, wherein a separation distance between the second fixing unit and the heat dissipating chassis is substantially the same as a thickness of the driving chip.

9. The display device of claim 7, wherein a separation distance between the wing unit and the heat dissipating chassis is substantially the same as the thickness of the driving chip.

10. The display device of claim 1, wherein the flange is disposed between two flexible printed circuit boards that are disposed adjacent to each other.

11. The display device of claim 1, wherein the heat dissipating chassis is in contact with a second surface of the flexible printed circuit board.

12. The display device of claim 11, wherein the heat dissipating member is disposed between the heat dissipating chassis and the second surface of the flexible printed circuit board.

13. The display device of claim 1, wherein the first fixing unit has a first coupling hole configured to be coupled to the bottom chassis.

14. The display device of claim 1, wherein the second fixing unit has a second coupling hole configured to be coupled to the heat dissipating chassis.

15. The display device of claim 1, wherein the bottom chassis has a groove configured to guide the first fixing unit.

16. A display device, comprising:
a display panel;
a plurality of flexible printed circuit boards disposed in a row and coupled to the display panel, wherein a gap is formed between adjacent flexible printed circuit boards;
a plurality of flanges comprising a first wing unit and second wing unit, wherein each of the flanges is respectively disposed in the gap between the adjacent flexible printed circuit boards, and wherein each of the first wing unit and the second wing unit are in contact with one of the adjacent flexible printed circuit boards; and
a heat dissipating chassis coupled to the plurality of flanges.

17. The display device of claim 16, further comprising a heat dissipating member disposed between the flanges and the flexible printed circuit boards.

18. The display device of claim 16, wherein the gap is substantially a same width as a width of each of the flanges.

19. The display device of claim 16, wherein the plurality of flanges each further comprises a coupling hole configured to connect the plurality of flanges to the heat dissipating chassis.

20. The display device of claim 16, wherein the plurality of flanges each further comprises an insulating member.
